(19) United States
(12) Patent Application Publication
(10) Pub. No.: US 2008/0153284 A1
(43) Pub. Date: Jun. 26, 2008

(54) Method of Manufacturing Semiconductor Device

(76) Inventor: JAE HONG KIM, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/862,313

(22) Filed: Sep. 27, 2007

(30) Foreign Application Priority Data
Dec. 21, 2006 (KR) 10-2006-0131458

(51) Int. Cl. H01L 21/4763

(52) U.S. Cl. 438/618; 257/E21.495

(57) ABSTRACT

Provided is a method of manufacturing a semiconductor device. In the method according to an embodiment a first electro-chemical plating process using a CuCl₂ solution is performed to form a first copper buried layer on a seed layer. A second electro-chemical plating process using a CuSO₄ solution is performed to form a second copper buried layer on the first copper buried layer. Then, a chemical mechanical polishing process can be performed to form a metal line from the first and second copper buried layers formed in a trench and a via hole. Through this method, the generation of a void in the metal line is restrained, and uniform metal lines can be formed.

### CROSS-REFERENCE TO RELATED APPLICATIONS

The present application claims the benefit under 35 U.S.C. §1119 of Korean Patent Application No. 10-2006-0131458, filed Dec. 21, 2006, which is hereby incorporated by reference in its entirety.

### BACKGROUND

To achieve the high performance and high integration of semiconductor devices, metal lines having multi-layered structures are widely used. The metal lines have mainly been formed of aluminum. However, recently, copper is being widely used for the metal lines.

Since it is not easy to perform a patterning process for a copper line layer by an etching process, the patterning process is performed using a damascene process and a chemical mechanical polishing (CMP) process.

FIG. 1 is a cross-sectional view illustrating a related art semiconductor device.

Referring to FIG. 1, an interlayer insulating layer 110 is formed on a semiconductor substrate 100. A trench 115 and a via hole 113 are sequentially formed in the interlayer insulating layer 110. A barrier layer 120 is formed in the via hole 113 and the trench 115 to prevent the diffusion of copper. A seed layer (not shown) is formed on the barrier layer 120 to easily form copper on the barrier layer 120.

The trench 115 and the via hole 113 are filled with copper through an electro-chemical plating process using the seed layer to form a copper line 130.

Referring to FIG. 2, in a copper plating method, an electrolyzer is filled with a copper solution, and a voltage is applied to a cathode 143 contacting the periphery of a wafer 141. Due to the voltage, copper ions receive electrons and therefore are reduced to copper on the wafer 141.

The cathode 143 contacts the periphery of the wafer 141, not the front surface of the wafer 141. Hence, a voltage drop caused by the internal resistance of the wafer 141 increases as it goes from an edge portion to a center portion of the wafer 141. The voltage drop is referred to as the terminal effect.

Because of the terminal effect, the amount of copper obtained through a reduction process at the edge portion of the wafer 141 is greater than the amount of copper obtained through the reduction process at the center portion of the wafer 141. Hence, the thickness of a copper line in the edge portion of the wafer 141 is different from that of a copper line in the center portion of the wafer 141. Since the copper lines are not uniformly formed, it is not easy to polish the copper lines using a CMP process, and the thickness of the polished copper line in the edge portion of the wafer 141 is different from that of the polished line in the center portion of the wafer 141.

Also, because of the terminal effect, the amount of copper obtained through the reduction process is greater at the edge portion of the wafer 141, and the via hole 113 is suddenly filled with a large amount of copper, causing generation of a void 117 such as illustrated in FIG. 1.

### BRIEF SUMMARY

Embodiments of the present invention provide a method of manufacturing a semiconductor device capable of restraining the generation of a void by minimizing a terminal effect and forming uniform lines.

Embodiments of the present invention also provide a method of manufacturing a semiconductor device capable of reducing a manufacturing process time.

In one embodiments a method of manufacturing a semiconductor device includes: forming an interlayer insulating layer including a via hole and a trench on a substrate; forming a seed layer on the interlayer insulating layer; performing a first electro-chemical plating process using a CuCl₂ solution to form a first copper buried layer on the seed layer; performing a second electro-chemical plating process using a CuSO₄ solution to form a second copper buried layer on the first copper buried layer; and performing a chemical mechanical polishing process to form a metal line in the trench and the via hole.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view illustrating a related art semiconductor device.

FIG. 2 is a view illustrating a cathode contacting a wafer.

FIGS. 3A to 3G are views illustrating a method of manufacturing a semiconductor device according to an embodiment of the present invention.

FIG. 4 is a graph illustrating a reduction mechanism for copper according to an embodiment.

FIG. 5 is a graph illustrating a reduction mechanism for copper according to another embodiment.

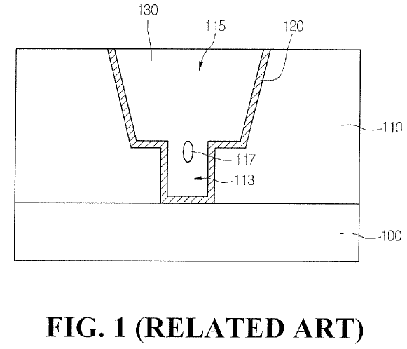

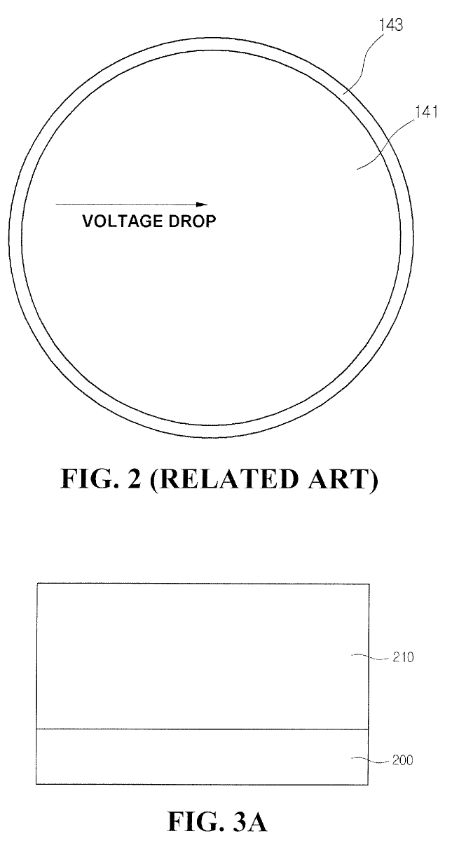

### DETAILED DESCRIPTION

Reference will now be made in detail to embodiments of the present disclosure, examples of which are illustrated in the accompanying drawings.

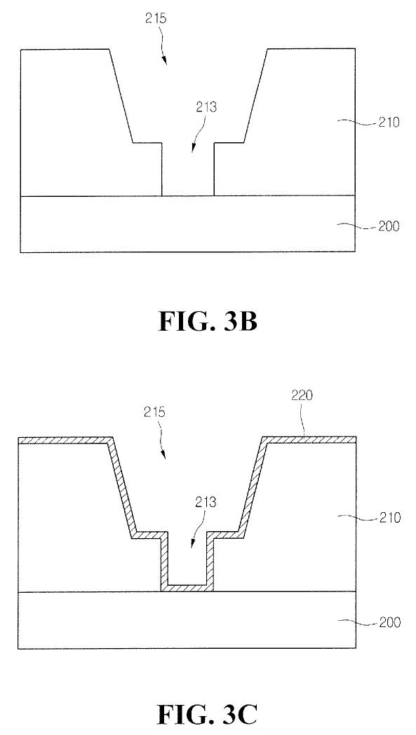

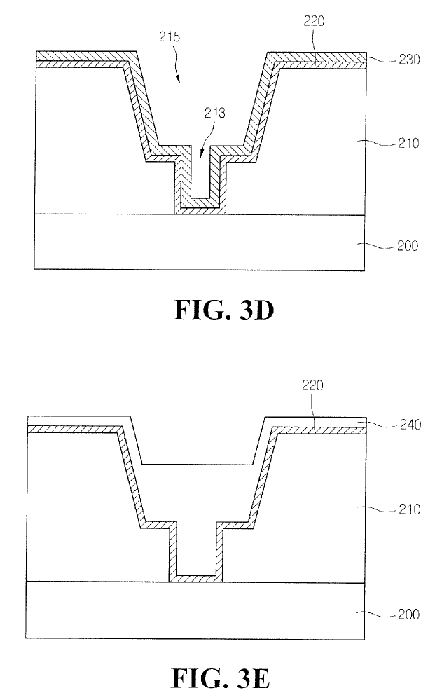

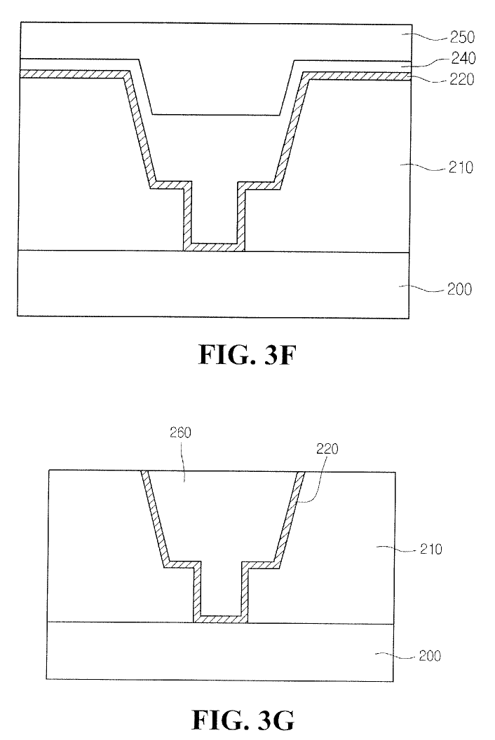

FIGS. 3A to 3G are views illustrating a method of manufacturing a semiconductor device according to an embodiment of the present invention.

Referring to FIG. 3A, an interlayer insulating layer 210 can be formed on a semiconductor substrate 200. The interlayer insulating layer 210 can be formed of, for example, boron silicate glass (BSGT), boron phosphorous silicate glass (BPSG), or undoped silicate glass (USG).

Before the interlayer insulating layer 210 is formed, a conductive device such as a metal line, a driving device such as a transistor, or a capacitor may be formed on the semiconductor substrate 200.

Referring to FIG. 3B, a trench 215 and a via hole 213 can be sequentially formed in the interlayer insulating layer 210 through a damascene process. In one embodiment, the trench 215 having a large width is formed, and then the via hole 213 is formed. The via hole 213 communicates with the trench 215 and has a width less than that of the trench 215.

Referring to FIG. 3C, to inhibit the diffusion of copper, a barrier layer 220 can be formed on the interlayer insulating layer 210 including the trench 215 and the via hole 213. The barrier layer 220 can be formed of, for example, tantalum, tantalum nitride, or a combination thereof. The barrier layer 220 is not essential and thus may be omitted.

Referring to FIG. 3D, to easily fill the via hole 213 with copper, a seed layer 230 can be formed in the via hole and trench. The seed layer 230 can be formed of copper. The seed layer 230 may be formed through a sputtering process or an electroless plating process.

Referring to FIG. 3E, a first electro-chemical plating process can be performed using a CuCl₂ solution to form a first copper buried layer 240 on the seed layer 230. In one embodiment, the first copper buried layer 240 can fill the via hole 213 and a portion of the trench 215 in the interlayer insulating layer 210.

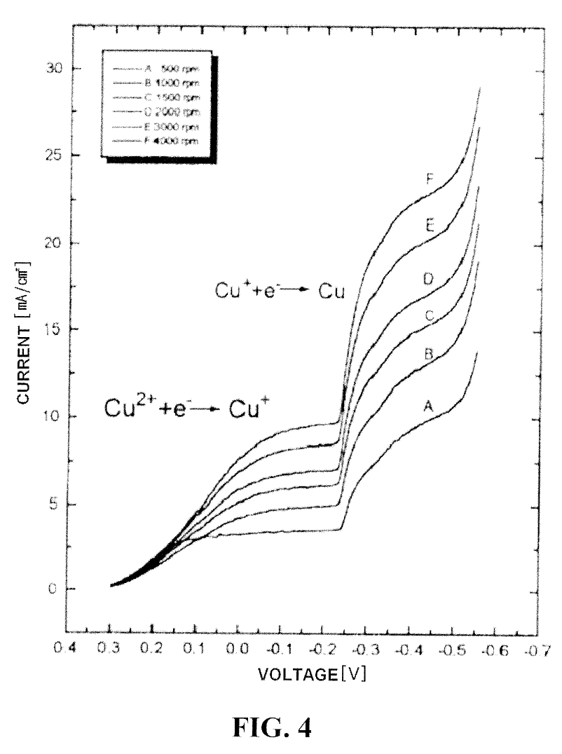

As illustrated in FIG. 4, CuCl₂ can be reduced through a one electron-two stage reaction. That is, a first stage reaction occurs where a Cu²⁺ ion reduces to a Cu⁺ ion by receiving an electron, and a second stage reaction occurs where a Cu⁺ ion reduces to a Cu atom by receiving an electron. As such, copper generated through the one-electron two-stage reaction is attached to the seed layer 230 of the interlayer insulating layer 210.

During the first electro-chemical plating process using the CuCl₂ solution, the generation of copper is delayed, and thus copper is slowly attached to the seed layer 230. In other words, since copper is gradually and slowly attached to the seed layer 230 on the interlayer insulating layer 230, a void is not formed in the via hole 213. If copper is rapidly attached to the seed layer 230, the generating speed of copper on a bottom surface of the via hole 213 is less than that of copper on a side surface of the via hole 213, and thus, a void may be generated.

Embodiments of the present invention delay the generation of copper on the bottom surface and side surface of the via hole 213. Hence, when the via hole 213 is filled with copper, a void is inhibited from being generated.

The horizontal axis of FIG. 4 represents voltage, and the vertical axis represents current. RPM (revolutions per minute) variations (A through F) are variables. Referring to FIG. 4, the current is increased until saturated (the first stage reaction). After that, the current is increased until saturated again (the secondary stage reaction). As such, the range in which the current is saturated is referred to as a diffusion layer. Hence, at the first stage reaction, a Cu²⁺ ion reduces to a Cu⁺ ion by receiving an electron. Thereafter, at the second stage reaction, a Cu⁺ ion reduces to a Cu atom by receiving an electron.

Embodiments of the present invention delay the generation of copper on the bottom surface and the side surface of the via hole 213. Hence, the terminal effect due the voltage drop toward the center portion of the semiconductor substrate 200 from the edge portion is minimized. Additionally, since a small nucleation of copper is formed, a first copper buried layer 240 having a uniform thickness across the wafer can be formed.

Subsequently, referring to FIG. 3F, a second electro-chemical plating process can be performed using a CuSO₄ solution to form a second copper buried layer 250 on the first copper buried layer 240. The second copper buried layer 250 having a large thickness covers the interlayer insulating layer 210 including the trench 215 in the interlayer insulating layer 210.

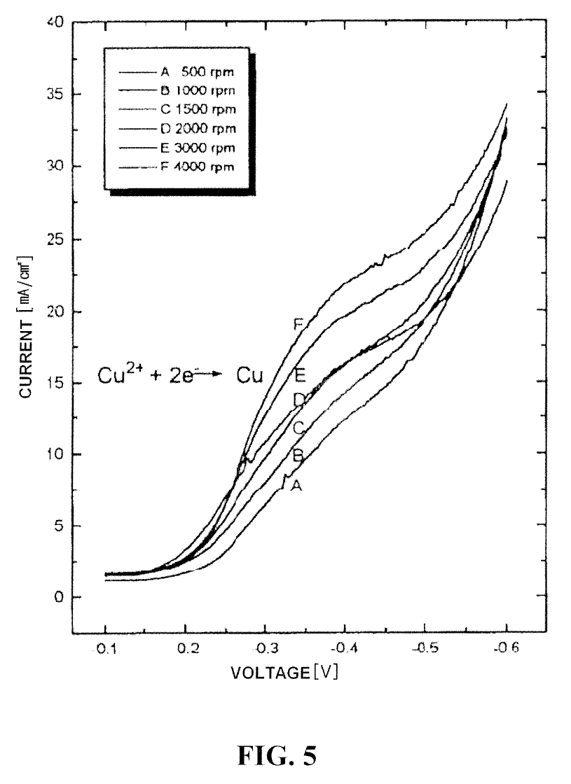

As illustrated in FIG. 5, CuSO₄ can be reduced through a two-electron one-stage reaction. That is, a first stage reaction occurs where a Cu²⁺ ion reduces to a Cu atom by receiving two electrons. As such, copper generated through the two-electron one-stage reaction is attached to the first copper buried layer 240.

During the second electro-chemical plating process using the CuSO₄ solution, the generation of copper is enhanced, and thus copper is rapidly attached to the first copper buried layer 240. In other words, since copper is rapidly attached to the first copper buried layer 240, the generating speed of copper is increased.

The horizontal axis of FIG. 5 represents voltage, and the vertical axis represents current. RPM variations (A through F) are variables. Referring to FIG. 5, the current is increased until saturated (the first stage reaction). As such, the range in which the current is saturated is referred to as a diffusion layer. Hence, at the first stage reaction, a Cu²⁺ ion reduces a Cu atom by receiving two electrons.

As described above, embodiments of the present invention minimize the terminal effect by delaying the generating of copper through the first electro-chemical plating process using the CuCl₂ solution. Hence, the generation of the void can be inhibited, and a uniform buried layer can be formed.

Embodiments can also reduce process time by enhancing and increasing the generating speed of copper through the second electro-chemical plating process using the CuSO₄ solution.

Subsequently, referring to FIG. 3G, a CMP process can be performed to remove the barrier layer 220 and the first and second copper buried layers 240 and 250 formed on the interlayer insulating layer 210. As a result, a metal line 260 is formed in the via hole 213 and the trench 215 of the interlayer insulating layer 210.

As described above, according to embodiments, when the first copper buried layer is formed in the via hole, the generation of copper is delayed by performing the first electro-chemical plating using a CuCl₂ solution. Hence, the terminal effect is minimized so that the generation of the via hole can be inhibited and the thickness of the copper buried layer can be uniform.

According to embodiments, when the second copper buried layer is formed in the trench, the generation of copper is enhanced by performing the second electro-chemical plating process using a CuSO₄ solution. Hence, the process time can be reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device, comprising:
forming an inter-layer insulating layer including a via hole and a trench on a substrate;
forming a seed layer on the interlayer insulating layer;
performing a first electro-chemical plating process using a CuCl₂ solution to form a first copper buried layer on the seed layer;
performing a second electro-chemical plating process using a CuSO₄ solution to form a second copper buried layer on the first copper buried layer; and
performing a chemical mechanical polishing process to form a metal line in the trench and the via hole.

2. The method according to claim 1, wherein the metal line comprises the first and second copper buried layers formed in the trench and via hole.

3. The method according to claim 1, wherein the first copper buried layer is formed in the via hole and a portion of the trench.

4. The method according to claim 1, wherein the second copper buried layer is formed on the interlayer insulating layer including in the trench.

5. The method according to claim 1, wherein copper ions of the CuCl₂ solution are reduced to copper atoms through a one-electron two-stage reaction.

6. The method according to claim 5, wherein the one-electron two-stage reaction comprises:
a first stage reaction where a Cu²⁺ ion reduces to a Cu⁺ ion by receiving an electron; and
a second stage reaction where a Cu⁺ ion reduces to a Cu atom by receiving another electron.

7. The method according to claim 1, wherein copper ions of the CuSO₄ solution are reduced to copper atoms through a two electron one-stage reaction.

8. The method according to claim 7, wherein the two-electron one-stage reaction comprises a first stage reaction where a Cu²⁺ ion reduces to a Cu atom by receiving two electrons.

9. The method according to claim 1, wherein the first copper buried layer is formed slowly through a one-electron two-stage reaction.

10. The method according to claim 1, wherein the second copper buried layer is formed rapidly through a two-electron one-stage reaction.

11. The method according to claim 1, further comprising forming a barrier layer on the interlayer insulating layer before forming the seed layer.
